(19) United States
(12) Patent Application Publication
(10) Pub. No.: US 2025/0008699 A1
(43) Pub. Date: Jan. 2, 2025

(54) IMMERSION TANK FOR COOLING ELECTRONICS

(71) Applicant: Laurel Technologies Partnership, Johnstown, PA (US)

(72) Inventors: Bryan Lanterman, St. Charles, MO (US); John Holst, Elsworth, WI (US); John Kroes, St. Louis, MO (US); Lance Koehn, Lakeville, MN (US); Trevor Hodgson, Hillsboro, MO (US); Joseph Richard Miller, Paradise Valley, AZ (US); Lawrence Creevy, Annapolis, MD (US)

(73) Assignee: Laurel Technologies Partnership, Johnstown, PA (US)

(21) Appl. No.: 18/632,034

(22) Filed: Apr. 10, 2024

Related U.S. Application Data
(60) Provisional application No. 63/524,337, filed on Jun. 30, 2023.

(51) Int. Cl. H05K 7/20; H05K 7/14

(52) U.S. Cl. CPC H05K 7/20781; H05K 7/1489; H05K 7/1494

(57) ABSTRACT

An immersion tank system includes an outer frame and an immersion tank disposed within the outer frame. A method for operating an immersion tank system includes inserting a payload into an immersion tank, flowing a source fluid from an external environment through tubing coupled to the immersion tank to a heat exchanger, cooling a working fluid using the heat exchanger and the source fluid, flowing the working fluid through one or more ports of the immersion tank, filling the immersion tank comprising the payload via the one or more ports to a predetermined level with the working fluid, transferring heat from the payload to the working fluid, exhausting gas and/or liquid from one or more vents defining a top surface of the immersion tank, and engaging one or more variable speed pumps for flowing the working fluid to the heat.

### CROSS REFERENCE TO RELATED APPLICATIONS

This application claims priority to U.S. Provisional Application No. 63/524,337 filed on Jun. 30, 2023, the contents of which are incorporated by reference in their entirety for all purposes.

### BACKGROUND OF THE INVENTION

Large scale server systems or any power dense electronic systems that perform high density computing generate and/or dissipate a large amount of heat during their operation. Furthermore, thermal management for electronics that generate heat as a byproduct of their primary function may benefit from cooling systems. These servers are often rack mounted and fans are built into the system to cool the rack of servers.

Despite the progress made in the area of high density computing systems, there is a need in the art for improved methods and systems related to cooling of high density computing systems.

### SUMMARY OF THE INVENTION

The present disclosure generally relates to immersion cooled systems and in particular to thermal management for high density computing.

According to one embodiment, an immersion tank system includes an outer frame and an immersion tank disposed within the outer frame. The immersion tank further includes one or more ports, one or more pumps, a control system, one or more sensors, and a heat exchanger.

The immersion tank system may include various optional embodiments. The one or more ports may fill or drain the immersion tank. The one or more ports may be disposed on a surface of the immersion tank. The surface may be a bottom surface of the immersion tank. The one or more pumps may be variable speed pumps. The immersion tank system may further include sliding rails. The immersion tank system may further include a shock cage disposed within the outer frame and the shock cage may include a front access cover. Shock mounts coupled to the outer frame may provide shock absorption for the immersion tank. The immersion tank may slide into and out of the shock cage on the sliding rails. The immersion tank may further include a sealed access cover. At least one of the one or more sensors may be a leak detection sensor. At least one of the one or more sensors may be a fluid level sensor. At least one of the one or more sensors may be a tank breather health sensor. At least one of the one or more sensors may be a fluid quality sensor. The heat exchanger may include a brazed plate heat exchanger. The immersion tank may vent into an expansion tank.

According to another embodiment, a method for operating an immersion tank system adaptable for multiple environments includes inserting a payload into an immersion tank, flowing a source fluid from an external environment through tubing coupled to the immersion tank to a heat exchanger, cooling a working fluid using the heat exchanger and the source fluid, flowing the working fluid through one or more ports of the immersion tank, filling the immersion tank comprising the payload via the one or more ports to a predetermined level with the working fluid, transferring heat from the payload to the working fluid, and exhausting gas and/or liquid from one or more vents defining a top surface of the immersion tank. The gas and/or liquid is exhausted into an expansion tank coupled to the immersion tank. The method further includes engaging one or more variable speed pumps for flowing the working fluid to the heat. Various steps may be repeated until the payload is removed from the immersion tank.

The method may include various optional embodiments. The method may further include monitoring leaks using one or more control sensors in a shock cage enclosing the immersion tank. The method may further include monitoring a health metric of the working fluid using a fluid quality sensor. The method may further include monitoring a fluid level of the working fluid in the expansion tank using a fluid level sensor. The method may further include draining the working fluid from the immersion tank via the one or more ports prior to removing the payload from the immersion tank.

According to yet another embodiment, a method for accessing an immersion tank system includes providing an immersion tank including one or more ports, one or more variable speed pumps, a control system, one or more control sensors, one or more health sensors, and a heat exchanger. The method further includes removing a shock cage front access panel from a shock cage enclosing the immersion tank, attaching a pump, and draining a working fluid from the immersion tank through the one or more ports, sliding the immersion tank out of the shock cage, removing an immersion tank cover from the immersion tank, and removing a payload from the immersion tank system.

The method may include various optional embodiments. The method may further include monitoring leaks using one or more control sensors in the shock cage enclosing the immersion tank. The method may further include monitoring a health metric of the working fluid using a fluid quality sensor. The method may further include monitoring a fluid level of the working fluid in an expansion tank in fluid communication with the immersion tank using a fluid level sensor. The method may further include draining the working fluid from the immersion tank via the one or more ports prior to removing the payload from the immersion tank.

Numerous benefits are achieved by way of the present disclosure over conventional techniques. Embodiments of the present invention implement single phase immersion cooling that enable increased compute density, reduces power consumption, increases reliability, and reduces ambient noise. Embodiments of the present invention further reduce the footprint of the cooling system and reduces the risk of forward incompatibility with future high power electronics. Embodiments of the immersion cooling system described herein optimize cabinet space, provides modularization, optimize cooling, and enable a higher payload compute density. These and other embodiments of the disclosure, along with many of its advantages and features, are described in more detail in conjunction with the text below and corresponding figures.

### DESCRIPTION OF THE DRAWINGS

FIG. 1 is a perspective view of an immersion tank system according to an embodiment of the present invention.

FIG. 2A is a block diagram of an immersion tank system according to an embodiment of the present invention.

FIG. 2B is a block diagram of the immersion tank illustrated in FIG. 2A according to an embodiment of the present invention.

FIG. 2C is a block diagram of the fluid sub-system illustrated in FIG. 2A according to an embodiment of the present invention.

FIG. 3 is a side view of an immersion tank system according to an embodiment of the present invention.

FIG. 4 is a front view of an immersion tank system according to an embodiment of the present invention.

FIG. 5 is an exploded perspective view of an immersion tank system according to an embodiment of the present invention.

FIG. 6A is a perspective view of an immersion tank according to an embodiment of the present invention.

FIG. 6B is a front perspective view of a fluid sub-system of an immersion tank according to an embodiment of the present invention.

FIG. 6C is a rear perspective view of a fluid sub-system of an immersion tank according to an embodiment of the present invention.

FIG. 6D is a cross sectional side view of an immersion tank having a fluid sub-system according to an embodiment of the present invention.

FIG. 7 is a flowchart of a method according to an embodiment of the present invention.

### DETAILED DESCRIPTION OF SPECIFIC EMBODIMENTS

The present disclosure generally relates to immersion cooled systems and in particular to thermal management for high density computing.

As the demand for high density computing and storage resources continues to expand, limitations arise surrounding available space for expansion, building and equipment costs, and communication latency. The increasing amount of processing power and storage placed on a single server, the number of servers placed in a single rack, and/or the number of servers and/or rails deployed on a single server farm create significant thermal challenges. With increased demands for high-performance embedded systems, air cooling technologies are unable keep pace with the shrinking sizes and increasing capabilities of computer hardware. Moreover, conventional fan-based cooling systems require large amounts of power and costs associated therewith. Additionally, cooling of electronic components with air requires special consideration for air-quality parameters including temperature, humidity, and airborne particulate and contamination. Accordingly, embodiments of the present invention provide improved methods and systems related to cooling of server systems.

This problem is amplified by Infrastructure as a Service (IaaS) initiatives. Some commercial markets have implemented immersion technology in data centers to address the computing density and cooling problem. Shipboard computing, in particular shipboard cloud computing and advanced networking, significantly increases requirements for computational resources in a constrained environment. Shipboard may include all maritime vessels such as submarines or the like and sea-borne platforms such as oil rigs. Thus, there is a need for increased computational compacity systems that address shipboard environment restrictions such as size, power, cooling, weight, shock, vibration, and the like. The system as described herein may be applied to any other mobile or stationary applications using ruggedized edge systems such as oil, gas, or the like.

Various embodiments of the present disclosure provide an immersion tank system for cooling electronic circuits. The immersion tank system includes an immersion tank. For example, the immersion tank system includes a rugged immersion tank. One or more components of the immersion tank system or the immersion tank is environmentally sealed using compression gaskets, retained screws, and/or latches that enable portable and transportable operation of the immersion tank. For example, the environmental sealing enables the immersion tank to have a greater range of pitch, roll, and yaw motion compared to conventional immersion tanks that are unequipped to handle a wide range of motion. However, as would be appreciated by one having ordinary skill in the art upon reading the present disclosure, embodiments of the system described herein may be operated in more stationary but harsh environments. The immersion tank system described herein is equipped with a series of frames that provide shock and vibration tolerance, thereby enabling use of immersion tanks in relatively unstable environments such as environments encountered during shipboard operation, airborne operation, vehicular mounted operation, and the like. For example, the immersion tank may be a rugged immersion tank. The isolation cage discussed below, specifically the isolation mounts, mitigate the shock input. In some environments, where less rugged systems would fail, this system will function well without additional isolation. For example, the immersion tank may be integrated with a shock isolation cage for operation in a racked-in or racked-out state. Furthermore, the shock isolation and vibration tolerance accommodates commercial-off-the-shelf (COTS) systems and/or electronic hardware in addition to custom solutions that are designed or modified for immersion. An immersion tank as described herein may be removable from the outer frame and the shock cage and mounted in a standard rack, for example a naval rack, according to at least some embodiments.

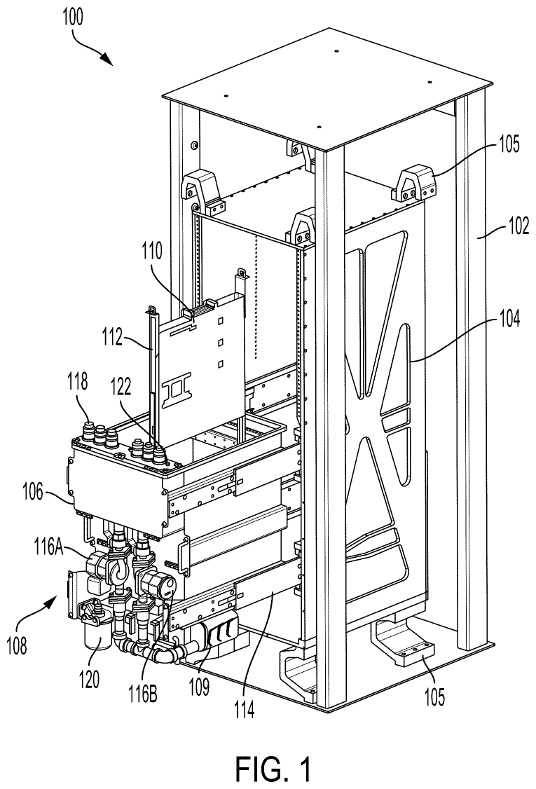

FIG. 1 is a perspective view of an immersion tank system according to an embodiment of the present invention. For example, FIG. 1 is a perspective view of a rugged immersion tank system. The system 100 includes an outer frame 102 that is mountable to a surface in an operating environment of the system 100. Various support features and/or side walls of the outer frame 102 are removed in this view for clarity. In various embodiments, the outer frame 102 may include sealing gasket assemblies and bonding surfaces to maintain alignment of and/or environmentally seal various components of the outer frame 102. The system 100 further includes a shock cage 104 disposed within the outer frame 102. The shock cage 104 is mounted inside the outer frame 102 according to various embodiments. Shock cage 104 may be mounted to the outer frame 102 using shock and/or vibration dampening components 105, according to at least some embodiments, for accommodating relatively unstable environments such as environments encountered during shipboard operation, airborne operation, vehicular mounted operation, and the like.

The system 100 includes an immersion tank 106 coupled to a fluid sub-system 108. The fluid sub-system 108 includes a heat exchanger 109. Heat exchanger 109 receives source fluid from an external environment, such as relatively cool recirculated water in a shipboard-mounted system. In other embodiments, the heat exchanger 109 receives source fluid from any external source. The heat exchanger 109 uses the source fluid to cool a working fluid (e.g., a dielectric fluid) in manner that would be appreciated by one having ordinary skill in the art upon reading the present disclosure. For example, the heat exchanger 109 cools the working fluid using the source fluid and the heat exchanger 109 outputs warmed source fluid.

According to various embodiments, a payload 110 is insertable in the immersion tank 106. In at least some embodiments, a payload 110 is insertable in the immersion tank 106 using a locking rack 112. The locking rack 112 is configured to hold a payload 110 in a vertical position (as shown in FIG. 1) to support the payload 110 as fluid drains, dries, or is otherwise removed from the payload 110. In various embodiments, the fluid is drained from the immersion tank 106 to a lower volume via one or more ports (not shown) prior to removing the payload 110 from the immersion tank 106. The immersion tank 106 may be mounted on sliding rails 114 that enable the immersion tank 106 to be slid into and out of the shock cage 104. For example, the immersion tank 106 mounting may be Electronic Industries Alliance (EIA-310) compliant. According to some embodiments, the immersion tank 106 is disposed on sliding rails 114 to enable top access. The combination of sliding rails 114 and top access (e.g., an environmentally sealed top access cover on the immersion tank 106, not shown) enables installation and/or removal or servicing of the payload that is often crucial for providing desired cooling capabilities. In some embodiments, the system 100 described herein includes a lift mechanism for facilitating loading and unloading of the payload 110 from the immersion tank 106.

The fluid sub-system 108 may include one or more variable speed pumps 116 for use in conjunction with tubing for flowing working fluid and/or source fluid through the system 100. In various embodiments, the one or more variable speed pumps 116 may be constant speed pumps or a combination of variable speed pump(s) and constant speed pump(s). The one or more variable speed pumps 116 may be engaged for flowing working fluid to a heat exchanger, in at least some embodiments. The fluid sub-system 108 may further include hose and cable management for optimizing space within the shock cage 104 and the outer frame 102.

According to various embodiments, the immersion tank 106 is coupled to one or more data and/or power input/output (I/O) cable connectors 118. The I/O cable connectors 118 provide data and/or power I/O to the system 100 in a manner that would be appreciated by one having ordinary skill in the art upon reading the present disclosure.

In various embodiments, the fluid sub-system 108 includes one or more filters 120 for filtering water and/or particulates from the working fluid. A filter 120 for the working fluid is provided in at least some embodiments to provide moisture and particulate removal. Monitoring of accumulated moisture in the filter 120 may also be provided to deliver a maintenance alert to replace the filter canister when a fluid level inside the containment reservoir is full.

The immersion tank 106 includes one or more vents 122 for exhausting gas and/or fluid from the immersion tank 106 into an expansion tank (not shown) and the expansion tank exhausts into a tank breather coupled thereto. For example, working fluid expands in the immersion tank 106 when the payloads 110 are warmed through use and then cooled by the working fluid. Gas may be exhausted through one or more vents 122 defining a top surface of the immersion tank 106, as shown in FIG. 1, as the working fluid expands. As the working fluid contracts, air is sucked in through a desiccant that dries the air thereby ensuring moisture (e.g., water vapor) does not enter the system 100. For example, the immersion tank 106 may include a vent at each corner of the top surface of the immersion tank 106. The one or more vents 122 enable fluid expansion within the immersion tank 106. The one or more vents 122 may be a multiport vent that assists in fluid level and pressure control as the temperature and dynamic conditions of the immersion tank 106 change. In at least some embodiments, the one or more vents 122 may be one-way exhaust vents that do not allow gas and/or fluid to return to the immersion tank 106. In exemplary embodiments, the one or more vents 122 allow for the passage of air out of and into the immersion tank 106 as the fluid level in the immersion tank 106 changes. Accordingly, the pressure of the immersion tank 106 stays at or near atmospheric pressure and does not turn into a vacuum or pressure vessel.

According to various embodiments, the immersion tank 106 is fluidly connected to the expansion tank. When the system 100 is filled, air is pushed from the immersion tank 106 to the expansion tank and then air is further pushed through the expansion tank and the tank breather to atmosphere. The immersion tank 106 is otherwise sealed and the only interface the closed system has with external air is through one or more vents at the top of the expansion tank.

In various embodiments, the immersion tank 106 is filled from the bottom up from one or more ports (not shown) defining a bottom surface of the immersion tank 106. In other embodiments, the immersion tank 106 is filled from one or more surfaces other than from the bottom surface such that any air is exhausted upward and out of the immersion tank 106, as would be appreciated by one having ordinary skill in the art upon reading the present disclosure. The one or more ports may be located at or near the bottom surface of the immersion tank 106 according to some embodiments. The immersion tank 106 may be filled via the one or more ports to a predetermined level with working fluid. For example, the predetermined level may be set such that the payloads, such as payload 110, is substantially covered in working fluid. The predetermined level may be set such that the immersion tank 106 is filled to the appropriate level on the expansion tank, e.g., as much as possible without overflowing. As the immersion tank 106 is filled via the one or more ports, air may be moved toward the top surface of the immersion tank 106 by the working fluid filling the immersion tank. The one or more vents 122 exhaust the air from the immersion tank 106 into the expansion tank and from the expansion tank, air is exhausted into the atmosphere via the tank breather such that the immersion tank 106 may be as full as possible with working fluid. The one or more vents 122 in the immersion tank 106 prevent air bubbles from forming in the immersion tank 106 that may lead to uneven cooling. Air bubbles further contribute to excess fluid movement (e.g., sloshing) that can be created in a mobile environment. For example, a completely full immersion tank 106 is easier to control during dynamic events than a partially full immersion tank due to sloshing of the fluid or the like. Accordingly, it is desirable that the immersion tank 106 is completely full is to ensure the payload 110 is never uncovered or no longer immersed in fluid at any time, specifically during dynamic events which may cause air bubbles to migrate within the immersion tank 106.

Embodiments of the present disclosure provide optimized utilization of cabinet space by maximizing payload volume and utilizing the server depth via vertically mounted payloads, such as payload 110. For example, embodiments of the present disclosure minimize the amount of cooling fluid used for a given payload. The system 100 described herein implements modularization of a cooling distribution unit (CDU), the immersion tank 106, and I/O. In some embodiments, the CDU of the system 100 optimizes the CDU with a 40 KW cooling capacity with 6° C. cooling water. The CDU of the system 100 may be connected to more than one immersion tank as would be appreciated by one having ordinary skill in the art upon reading the present disclosure. In other embodiments, the CDU may be less than 40 kW or greater than 40 kW, depending on the capacity of the immersion tank 106.

According to at least some embodiments of the present disclosure, the system 100 provides a higher payload compute density compared to conventional air cooled system by having an improved core count per socket, increased CPU and/or GPU sockets per motherboard, and multiple motherboards packaged in a single unit. Due to the removal or absence of fans and provisions for ducting air, the space these items would otherwise occupy in an air cooled system may be used for processing hardware in the immersion system described herein, thereby improving overall processing density.

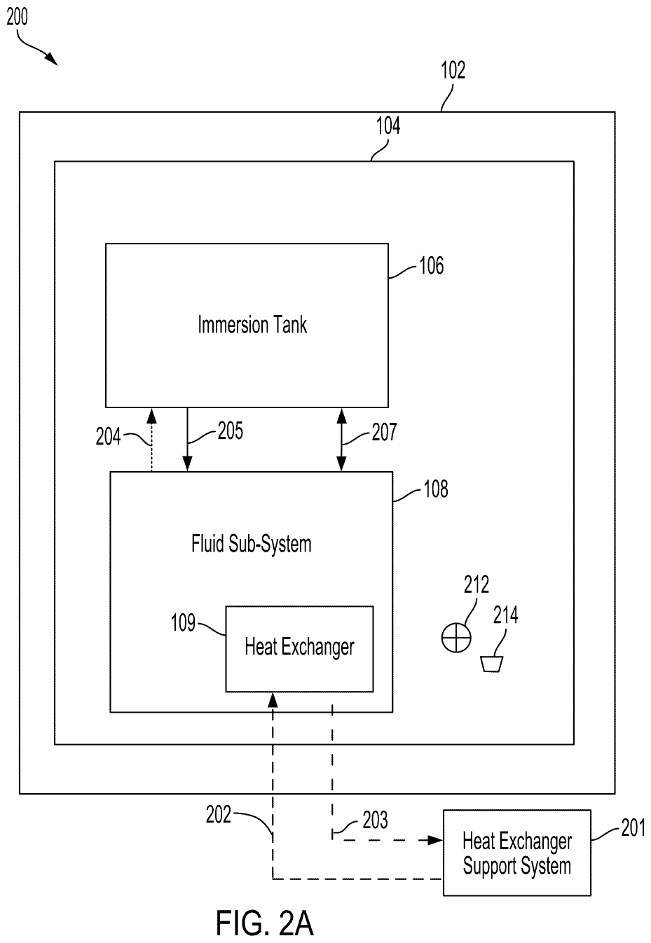

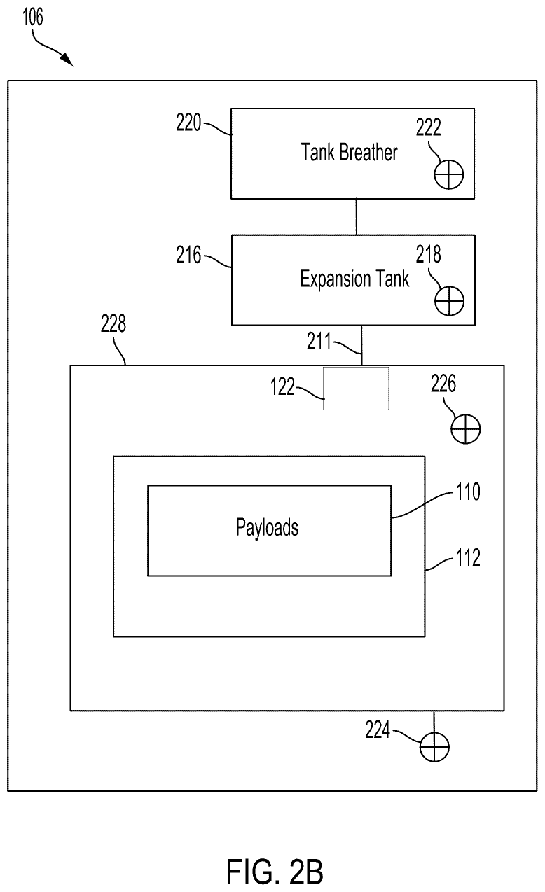

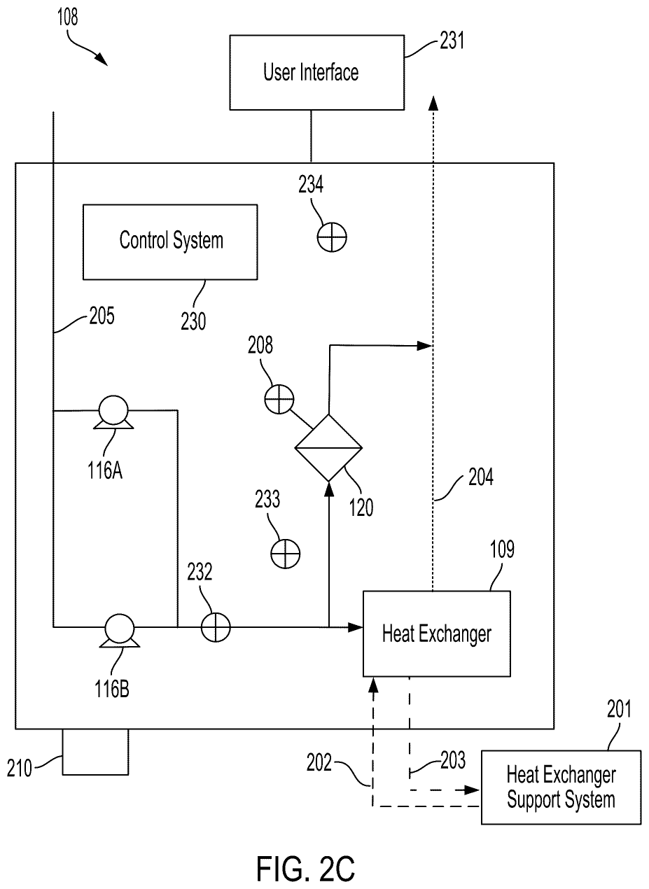

FIG. 2A is a block diagram of an immersion tank system according to an embodiment of the present invention. For example, FIG. 2A is a block diagram of a rugged immersion tank system. The description of system 100 described with respect to FIG. 1 is applicable to the description of the block diagram of a mobile immersion tank system. System 200 includes an outer frame 102. In at least some embodiments, the outer frame 102 is mountable to a surface within an operating environment. For example, the outer frame 102 may be mounted to one or more walls, pillars, other equipment, other structure, or the like, within a ship, plane, vehicle, other unstable environments, or the like. In various embodiments, the system 200 may be implemented into any existing cabinet other than the configuration shown in FIG. 2A, enabling embodiments of the present invention to be integrated into existing enclosures currently utilized to enclose air-cooled systems.

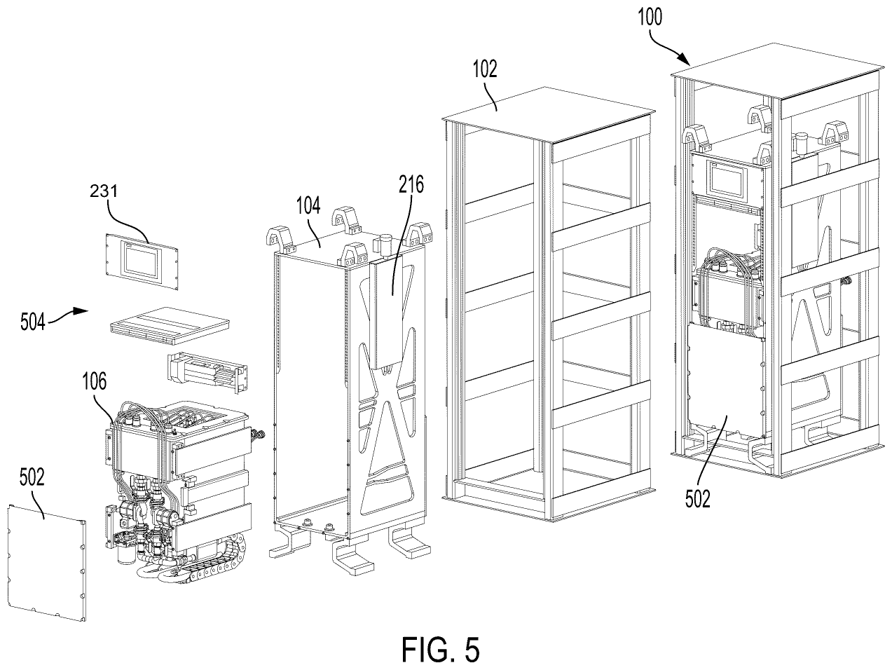

System 200 further includes a shock cage 104 disposed within the outer frame 102. In various embodiments, the shock cage 104 may alternatively be referred to as a secondary tank. In at least some embodiments, the shock cage 104 functions as a secondary containment tank to provide for fluid containment in addition to the fluid containment provided by the immersion tank 106. The immersion tank 106, or components thereof, is environmentally sealed. Additionally, the shock cage 104 provides a mechanical shock and/or vibration dampening function and may include additional shock and/or vibration support components in order to accommodate unstable environments encountered during shipboard operation, airborne operation, vehicular mounted operation, or the like. The shock cage 104 provides a rigid structure to support components stored therein during normal operation and during dynamic events. The isolation system external and connected to the shock cage 104 attenuates the bulk of the dynamic inputs. For example, the shock cage 104 is configured to withstand dynamic events such that the system 200 maintains functionality during the dynamic events. In various embodiments, the shock cage 104 provides rigid support for the immersion tank 106 disposed therein during stationary operation and during dynamic events that may otherwise distort less rigid, conventional structures. Thus, the isolation system coupled to the shock cage 104 functions to provide not only shock absorption, but as a secondary fluid containment chamber in the event of fluid leakage from the immersion tank 106 and/or the fluid sub-system. The shock cage 104 is rigid and provides support to secure the immersion tank 106 and other system components in an isolated environment. For example, the shock cage 104 may be coupled to a partial door or a front access panel 502 as shown in FIG. 5 that seals the lower portion of the front of the shock cage 104 so that any fluid that may leak from immersion tank 106 is contained within the shock cage 104.

In various embodiments, a fluid sub-system 108 may be coupled to or integrated with the immersion tank 106. As discussed more fully in relation to FIG. 2C, the fluid sub-system 108 includes a heat exchanger 109. Heat exchanger 109 receives source fluid 202 from an external environment, such as relatively cool recirculated water in a shipboard-mounted system. In other embodiments, the heat exchanger 109 receives source fluid 202 that is cooled from any external source, for example, heat exchanger support system 201. The heat exchanger 109 cools a working fluid (e.g., a dielectric fluid) in manner that would be appreciated by one having ordinary skill in the art upon reading the present disclosure. For example, the heat exchanger 109 outputs cooled working fluid 204 to the immersion tank 106 using the source fluid 202 and the heat exchanger 109 outputs warmed source fluid 203 to be reused or otherwise disposed of (e.g., by heat exchanger support system 201). Warmed working fluid 205 is directed through the fluid sub-system 108 to be recooled and recirculated as would be appreciated by one having ordinary skill in the art upon reading the present disclosure.

In at least some embodiments, one or more leak detection sensors 212 as shown in FIG. 2A may be disposed within the shock cage 104. One or more leak detection sensors 212 may be used for monitoring leaks within the immersion tank 106, to be described in further detail below, into the shock cage 104. The shock cage 104 may further include a drain port 214 that seals any leaked fluid from the immersion tank 106, to be described in further detail below, into the shock cage 104. Thus, the shock cage 104 may act as a secondary retention vessel for any fluid in the system 200 that is released from the immersion tank 106.

According to various embodiments, command/control signals 207 may be exchanged between the immersion tank 106 and the fluid sub-system 108 in a manner that would be appreciated by one having ordinary skill in the art.

FIG. 2B is a block diagram of the immersion tank illustrated in FIG. 2A according to an embodiment of the present invention. In various embodiments, the system 200 includes an immersion tank 106 for storing payloads 110. Payloads 110 may include any form of data rails, server rails, etc. The immersion tank 106 may be an environmentally sealed dielectric immersion tank. A payload 110 is insertable in the immersion tank 106 using a locking rack 112 or other electronic hardware mounting. The locking rack 112 is configured to hold a payload 110 in a vertical position to support the payload 110 as fluid drains, dries, or is otherwise removed from the immersion tank 106, as described and shown with respect to FIG. 1. In various embodiments, the fluid is drained from the immersion tank 106 via one or more ports 210 of the fluid sub-system 108, to be described in further detail below at least with respect to FIG. 2C, prior to removing the payload 110 from the immersion tank 106. Port 210 may be for filling the immersion tank 106 with working fluid 204 and/or for draining working fluid 205 from the system 200. The one or more ports 210 may be integrated quick disconnect fill and drain ports for providing moisture ingress and egress control.

In various embodiments, the immersion tank 106 is in fluid communication with an expansion tank 216 via one or more vents 122 and vent tubing 211. The expansion tank 216 may be located at a remote location with respect to the immersion tank 106, for example, mounted on the shock cage 104. The immersion tank 106 is configured to vent excess working fluid into the expansion tank 216 through the vent tubing 211. For example, as a result of the working fluid increasing in temperature, the working fluid may expand in volume and vent through to the expansion tank 216. As the working fluid contracts in volume, the working fluid can flow from the expansion tank 216 to the immersion tank 106 through the vent tubing 211. The expansion tank 216 may be vented to the atmosphere. Thus, the expansion tank 216 is configured to receive any excess gas and/or liquid exhausted from the immersion tank 106 so that the immersion tank 106 is not pressurized during operation. In some embodiments, the expansion tank 216 is coupled to the shock cage 104, e.g., the expansion tank 216 may be disposed on an outer surface of the shock cage 104 and within the outer frame 102. The expansion tank 216 may include one or more fluid level sensors 218 for detecting an amount of fluid being captured in the expansion tank 216.

In various embodiments, the immersion tank 106 may further include a tank breather 220. The tank breather 220 enables air exchange between the expansion tank 216 and the atmosphere to ensure the immersion system 106 is not pressurized during operation. The tank breather 220 includes a desiccant for removing moisture from air within the system 200. The tank breather 220 may include a tank breather health sensor 222 that monitors the health (e.g., integrity) of the desiccant. The tank breather health sensor 222 may output a signal indicative of replacing the desiccant.

The immersion tank 106 may further include one or more sensors 224, e.g., a multi-property sensor. The one or more sensors 224 may include one or more fluid quality sensors. A fluid quality sensor may monitor health metrics, e.g., properties, of a working fluid flowed through the system 200. For example, the one or more sensors 224 may include one or more fluid quality sensors that monitor a dielectric constant, a temperature, dielectric degradation, etc. Dielectric fluid quality monitoring may also be provided to monitor density or viscosity among other fluid properties to ensure a proper immersion environment for electronics. According to at least some embodiments, measurements derived from the one or more sensors 224 may affect the flow rate and/or operation of pumps in the system 200. In some embodiments, the immersion tank 106 includes a top cover sensor 226 that indicates whether an environmentally sealed access cover 228 of the immersion tank 106 is in an open position and/or a closed position.

FIG. 2C is a block diagram of the fluid sub-system illustrated in FIG. 2A according to an embodiment of the present invention. One or more variable speed pumps 116 control the flow of the cooled working fluid 204, and the warmed working fluid 205. The one or more variable speed pumps 116 may include at least two variable speed pumps. The one or more variable speed pumps 116 may be coupled with or otherwise function in conjunction with one or more valves and/or one or more check valves for further controlling the flow rate of cooled working fluid 204, and/or the warmed working fluid 205 through the system 200. According to various embodiments, the one or more variable speed pumps 116 of the immersion tank 106 described herein may be hot swapable pumps for uninterrupted cooling of the immersed electronics. The one or more variable speed pumps 116 may be a set of redundant variable speed pumps. Pump speed may be changed based on the temperature of the dielectric fluid (e.g., the working fluid) recorded by the temperature sensors of the one or more sensors 224 described above.

According to at least some embodiments, the fluid sub-system 108 includes a filter 120 for filtering water and/or particulates from the warmed working fluid 205. A filter 120 for the warmed working fluid 205 is provided in at least some embodiments to provide moisture and particulate removal. Monitoring of accumulated moisture in the filter 120 may also be provided to deliver a maintenance alert to replace the filter canister when a water/moisture level inside the containment reservoir is full. For example, a corresponding filter replacement sensor 208 for monitoring criteria indicative of whether the filter 120 should be replaced.

Referring once again to FIG. 2C, the fluid sub-system 108 may include a control system 230 for receiving data and/or measurements from any of the sensors of the immersion tank 106 and/or processing the data and/or measurements, for example, to modify the flow rate controlled by the one or more variable speed pumps 116. The fluid sub-system 108 includes a programmable logic controller (PLC) system control in an exemplary embodiment. A control system for the system 200 may be implemented at other locations within the system 200 and may include other means than a PLC system control. The system 200 includes various system control sensors and system health sensors to monitor the characteristics of the various fluids and components of the system 200. Additionally, the control system 230 works in conjunction with a user interface 231 that enables an operator to monitor and control the system 200. Monitoring and/or controlling the system 200 may be performed locally or remotely according to various embodiments. In various embodiments, the fluid sub-system 108 further includes a temperature sensor 232, a first pressure sensor 233, and a second pressure sensor 234 for monitoring the temperature and pressure, respectively, in the system 200. Temperature sensor 232 is utilized to measure the temperature of the warmed working fluid prior to entering the heat exchanger 109. The pressure differential between first pressure sensor 233 and second pressure sensor 234 can be utilized to compute the flow rate through the heat exchanger 109. Data and/or measurements from the temperature sensor 232, the first pressure sensor 233, and the second pressure sensor 234 may be further used by the control system 230, either individually or in combination, to adjust parameters within the system 200 such as temperature, flow rates for the one or more variable speed pumps 116, etc.

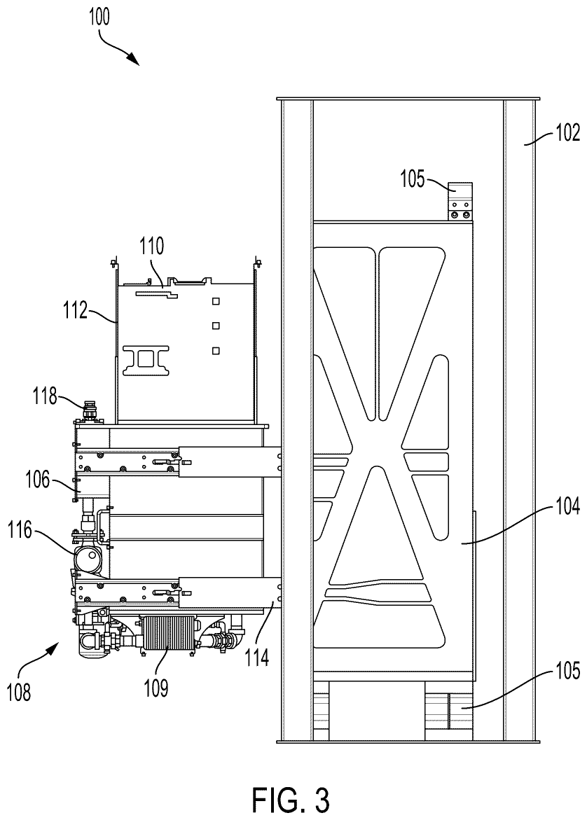

FIG. 3 is a side view of an immersion tank system according to an embodiment of the present invention. For example, FIG. 3 is a side view of a rugged immersion tank system. The description of system 100 and system 200 described with respect to FIGS. 1-2 is applicable to the description of the side view of an immersion tank system. Visible in this view, the outer frame 102 provides mechanical support for the shock cage 104. The shock cage 104 is mounted to the outer frame 102 using shock and/or vibration dampening components 105 in this embodiment. In other embodiments, the outer frame is shock/vibration isolated and shock and/or vibration dampening components 105 are optional. Sliding rails 114 enable the immersion tank 106 and the fluid sub-system 108 to be racked in and racked out of the shock cage 104.

The fluid sub-system 108 coupled to the immersion tank 106 includes a heat exchanger 109. The heat exchanger 109 is configured to transfer heat between working fluid (e.g., dielectric fluid) and source fluid (chilled water sourced from an external environment, such as ocean water when the system 200 is shipboard).

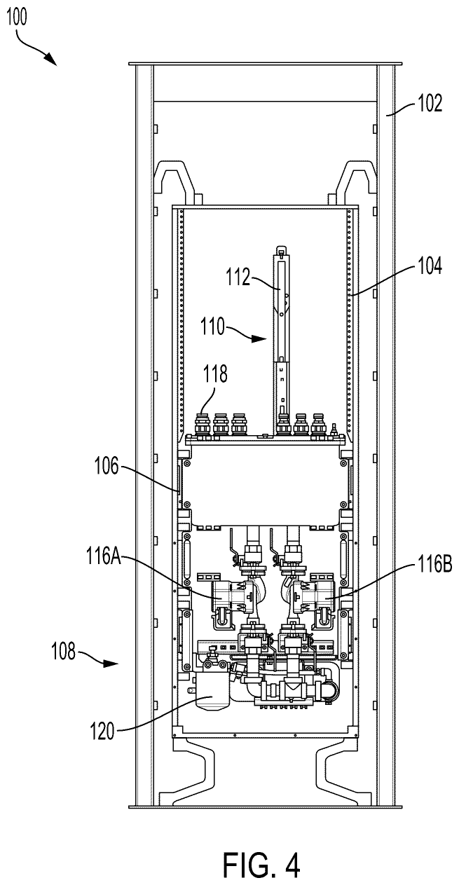

FIG. 4 is a front view of an immersion tank system according to an embodiment of the present invention. For example, FIG. 4 is a front view of a rugged immersion tank system. The description of system 100 and system 200 described with respect to FIGS. 1-3 is applicable to the description of the front view of an immersion tank system. Visible in this view, the fluid sub-system 108 may include one or more variable speed pumps 116 for use in conjunction with tubing for flowing working fluid through the system 100. The fluid sub-system 108 may further include hose and cable management for optimizing space within the shock cage 104 and the outer frame 102. The fluid sub-system 108 further includes a filter 120 for filtering water and/or particulates from the working fluid as the working fluid is pumped through associated tubing using the one or more variable speed pumps 116.

FIG. 5 is an exploded perspective view of an immersion tank system according to an embodiment of the present invention. For example, FIG. 5 is an exploded perspective view of a rugged immersion tank system. The description of system 100 and system 200 described with respect to FIGS. 1-4 is applicable to the description of the exploded perspective view of an immersion tank system shown in FIG. 5. The system 100 is illustrated in an assembled form with the assembled immersion tank system including an outer frame 102, a shock cage 104, and an immersion tank 106. Visible in this view, the shock cage 104 includes a front access panel 502 that is mounted to the front of the shock cage 104. The front access panel 502 seals the lower portion of the front of the shock cage 104 so that any fluid that may leak from immersion tank 106 (e.g., working fluid) is contained within the shock cage 104, thereby performing the secondary fluid containment function of the shock cage 104. When the front access panel 502 is removed from the shock cage 104, an operator may slide the immersion tank 106 out of the shock cage 104 in order to gain access to the immersion tank 106 and payloads stored within the immersion tank 106. The payloads stored within the immersion tank 106 may be accessed from an environmentally sealed access cover located on the top surface of the immersion tank 106, to be described in further detail below.

According to at least some embodiments, the system 100 includes a control system 230 coupled to the immersion tank 106 and/or the shock cage 104 within the outer frame 102. The payload data management system 504 may include an external switch and any other electronic system hardware known in the art. For example, at least some embodiments described herein include an immersed network switch for internal data distribution that reduces I/O. Reduced I/O on the immersion tank reduces the number of possible leak or failure points. At least some of the embodiments of the present disclosure include a bulkhead and/or connectorized cable interface that enables power and data cables to pass through the immersion tank access cover while at the same time providing a sealed interface.

Visible in this view, the system 100 includes an expansion tank 216. In some embodiments, the expansion tank 216 is coupled to the shock cage 104, e.g., the expansion tank 216 may be disposed on an outer surface of the shock cage 104 and within the outer frame 102, as shown in FIG. 5.

According to at least some embodiments, system 100 may be used as a hybrid immersion cooling and air cooling system. For example, components capable of being air-cooled (not shown), such as solid state hard drives or the like, may be racked into a space between the immersion tank 106 and the topmost portion of the shock cage 104. Accordingly, system 100 is provides both immersion cooling and air cooling capabilities.

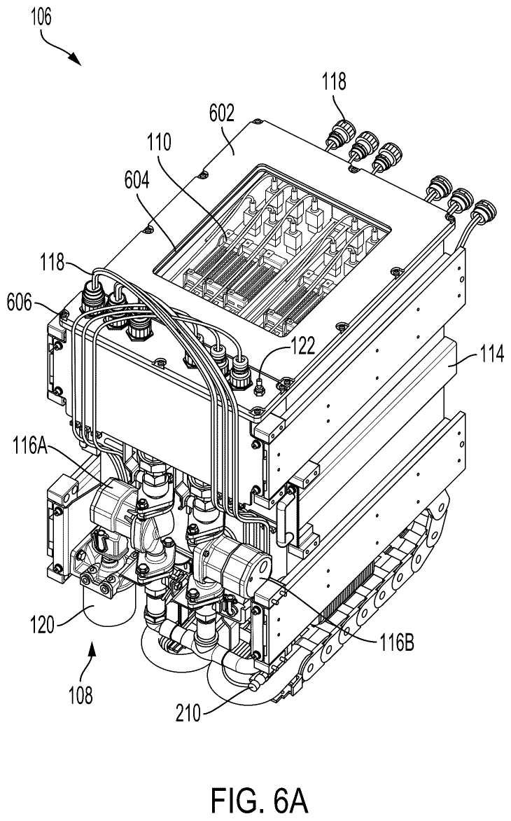

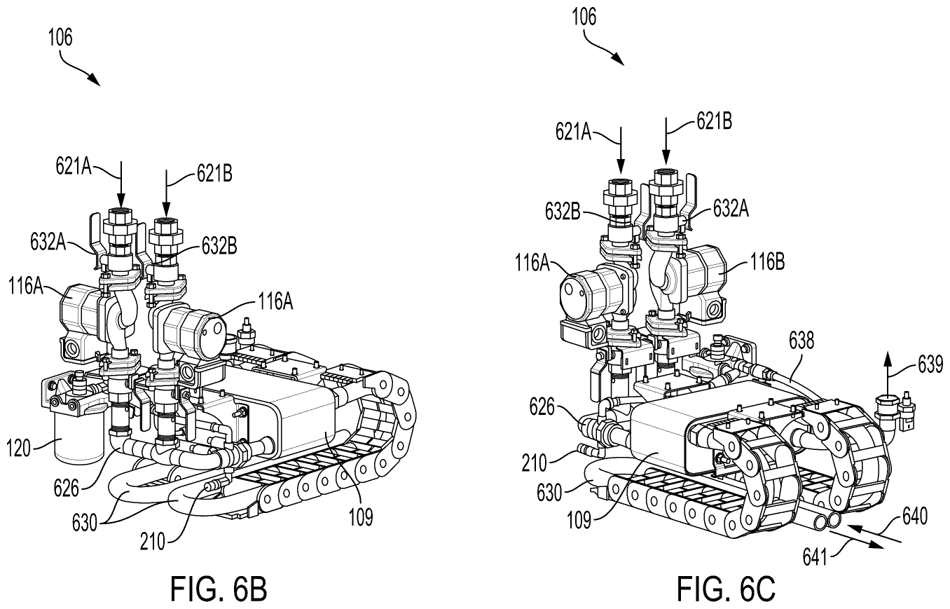

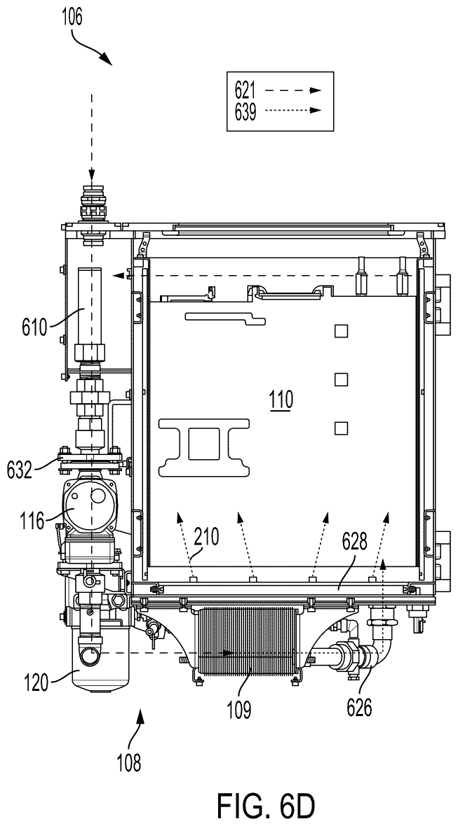

FIG. 6A is a perspective view of an immersion tank according to an embodiment of the present invention. The description of system 100 and system 200 described with respect to FIGS. 1-5 is applicable to the description of the immersion tank. Immersion tank 106 includes an access cover 602 defining a top surface of the immersion tank 106. The access cover 602 is an environmentally sealed access cover that prevents leaks from the immersion tank 106 into a shock cage. For example, the access cover 602 includes a gasket lining an outer perimeter of the access cover 602. The access cover 602 may be removed to access a payload 110 stored within the immersion tank 106. In at least some embodiments, the access cover 602 may include a viewing window 604 for enabling monitoring of the fluid level without removing the access cover 602. In at least some embodiments, the access cover 602 is secured to the immersion tank 106 using one or more fasteners 606 such as Screw and Washer Assemblies (SEMS) fasteners or the like. Other fasteners such as latches, or the like may be used to secure the access cover 602 to the immersion tank 106 in other embodiments. In various embodiments, I/O cable connectors 118 are disposed on the access cover 602 or on a top surface of the immersion tank 106 for providing data and/or power to the immersion tank 106. In other embodiments, the I/O connectors 118 are disposed elsewhere relative to the immersion tank 106 as would be determinable by one having ordinary skill in the art based on the intended application. In various embodiments, the immersion tank 106 further includes inclusive electromagnetic interference (EMI) gasketing to minimize radiated emissions. For example, the EMI gasketing may include metal impregnated elastomeric gaskets, other wave guide style gaskets or cover geometry, or the like.

The immersion tank 106 may be filled from the bottom of the immersion tank 106 via one or more ports 210. The one or more ports 210 may be integrated quick disconnect fill and drain ports. The one or more ports 210 provide working fluid to the immersion tank 106 that fills the immersion tank 106. Air is moved out of the immersion tank 106 by the introduction of the working fluid in the immersion tank 106 and the air is exhausted out of one or more vents 122 disposed on a top surface of the immersion tank 106.

Immersion tank 106 further includes sliding rails 114 that enable the immersion tank 106 to be racked in and racked out (e.g., slid into and slid out of) of a shock cage 104 as illustrated in FIG. 1, as described above. The immersion tank 106 is configured to slide into and out of the shock cage on the sliding rails 114 in a manner that would be appreciated by one having ordinary skill in the art upon reading the present disclosure.

Immersion tank 106 is in fluid communication with fluid sub-system 108 for flowing working fluid through the immersion tank 106. In various embodiments, the fluid sub-system 108 includes a filter 120 for filtering water and/or particulates from the working fluid. Monitoring of accumulated moisture in the filter 120 may be provided to deliver a maintenance alert to replace the filter canister when a water/moisture level inside the containment reservoir is full. The fluid sub-system 108 is described in further detail with respect to FIGS. 6B-6D below.

FIG. 6B is a front perspective view of a fluid sub-system of an immersion tank according to an embodiment of the present invention. The description of system 100 and system 200 and immersion tank 106 described with respect to FIGS. 1-6A is applicable to the description of the front perspective view of a fluid sub-system of an immersion tank. The fluid sub-system 108 flows working fluid (e.g., dielectric fluid) through an immersion tank and flows source fluid (e.g., chilled fluid from an external source) through a heat exchanger 109. The heat exchanger 109 may be a brazed plate heat exchanger according to various embodiments. The heat exchanger 109 inputs chilled source fluid through source fluid tubing 630 and outputs source fluid that has been warmed by the working fluid flowing in parallel through the heat exchanger 109 as would be understood by one having ordinary skill in the art upon reading the present disclosure. The heat exchanger 109 also includes working fluid tubing 626 for flowing warmed working fluid from the immersion tank to the heat exchanger 109 for heat transfer between the working fluid and the source fluid. According to various embodiments, warmed working fluid from the immersion tank is flowed to the heat exchanger 109 from the top of the immersion tank as illustrated by warmed working fluid directional flow 621.

The fluid sub-system 108 includes one or more variable speed pumps 116 for flowing the working fluid through the working fluid tubing 626. The one or more variable speed pumps 116 may be coupled with or otherwise function in conjunction with one or more valves 632 for further controlling the flow rate of the working fluid and/or the source fluid. According to various embodiments, the one or more variable speed pumps 116 may be a hot swapable pump for uninterrupted cooling of immersed electronics. The one or more variable speed pumps 116 may be redundant variable speed pumps.

According to various embodiments, the fluid sub-system 108 includes a port 210 for filling and/or draining working fluid from the immersion tank. The port 210 may be an integrated quick disconnect fill and drain port for providing working fluid ingress and egress control.

The fluid sub-system 108 may include a filter 120 for filtering water and/or particulates from the working fluid. A filter 120 for the dielectric fluid is provided in at least some embodiments to provide moisture and particulate removal. Monitoring of accumulated moisture in the filter 120 may also be provided to deliver a maintenance alert to replace the filter canister when a water/moisture level inside the containment reservoir is full.

FIG. 6C is a rear perspective view of a fluid sub-system of an immersion tank according to an embodiment of the present invention. The description of system 100 and system 200 and immersion tank 106 described with respect to FIGS. 1-6B is applicable to the description of the rear perspective view of a fluid sub-system of an immersion tank. Visible in this view, the fluid sub-system 108 includes a filter line 638 for directing working fluid from the fluid tubing 626 through the filter 120 (not visible in this view). The fluid sub-system 108 flows the cooled working fluid from the heat exchanger 109 to the bottom of the immersion tank as illustrated by cooled working fluid directional flow 639.

As illustrated in FIG. 6C, cooled source fluid directional flow 640 flows into the heat exchanger 109 and warmed source fluid directional flow 641 flows out of the heat exchanger 109. The warmed working fluid directional flow 621 and cooled working fluid directional flow 639 are shown in more detail with respect to FIG. 6D described in detail below.

FIG. 6D is a cross sectional side view of an immersion tank having a fluid sub-system according to an embodiment of the present invention. The description of system 100 and system 200 and immersion tank 106 described with respect to FIGS. 1-6C is applicable to the description of the side view of an immersion tank having a fluid sub-system. The flow of the warmed working fluid is represented by fluid directional flow 621 and the flow of the cooled working fluid is represented by fluid directional flow 639 in FIG. 6D.

After passing through heat exchanger 109 for cooling the working fluid, the cooled working fluid passes through the working fluid tubing 626 and enters distribution plenum 628 of the immersion tank 106. The distribution plenum 628 provides directional routing of the fluid to direct the flow of cooled working fluid that was cooled in the heat exchanger 109 into the bottom of the immersion tank 106. The cooled working fluid entering the bottom of the immersion tank 106 then flows upward, passing over and between the payloads 110 and/or other electronics mounted in the immersion tank 106. In the embodiment illustrated in FIG. 6D, a single payload 110 is illustrated.

As the working fluid flows past the payloads, the working fluid moves toward the top of the immersion tank 106, both by natural convection due to the heating of the working fluid and by forced flow due to the distribution plenum 628. As illustrated in FIG. 6D, warmed working fluid exits the immersion tank 106 and passes through screen 610 before entering the one or more variable speed pumps 116 and passing partial flow through filter 120. Although only a single variable speed pump is illustrated in the cross sectional view illustrated in FIG. 6D, FIGS. 6B and 6C illustrate the one or more variable speed pumps 116 utilized in some embodiments. Continuous partial filtering of the working fluid can be performed by the filter 120 to remove particles and moisture from the working fluid to maintain a clean and moisture free working fluid. In some embodiments, the filter 120 is a partial flow filter and not all of the working fluid passes through the filter 120 during each cycle.

To access the contents of the immersion tank 106 (i.e., the payloads mounted in the immersion tank), the working fluid may be drained from the immersion tank 106 through the bottom of the immersion tank 106 via a fill port (not shown in FIG. 6D, fill port may refer to fill port 210 as shown in FIGS. 6B and 6C). In exemplary embodiments, the fill port is a single port that may be used for both filing and draining the working fluid. The fill port may be located on or proximate to the bottom surface of the immersion tank 106 in at least some embodiments. In other embodiments, a fill port may be located anywhere on the immersion tank 106 such as on one or more sidewalls, through a top surface, on a secondary bottom surface (e.g., a surface toward the bottom of the immersion tank 106 which is not the bottommost surface), etc.

According to various embodiments described herein, payloads are not air cooled and no fans are used to cool the system. Elimination of fans results in lower ambient noise. Embodiments of the present disclosure provide immersion subsystems having Air Borne Noise (ABN) of less than 40 dBA (e.g., less than a quiet office).

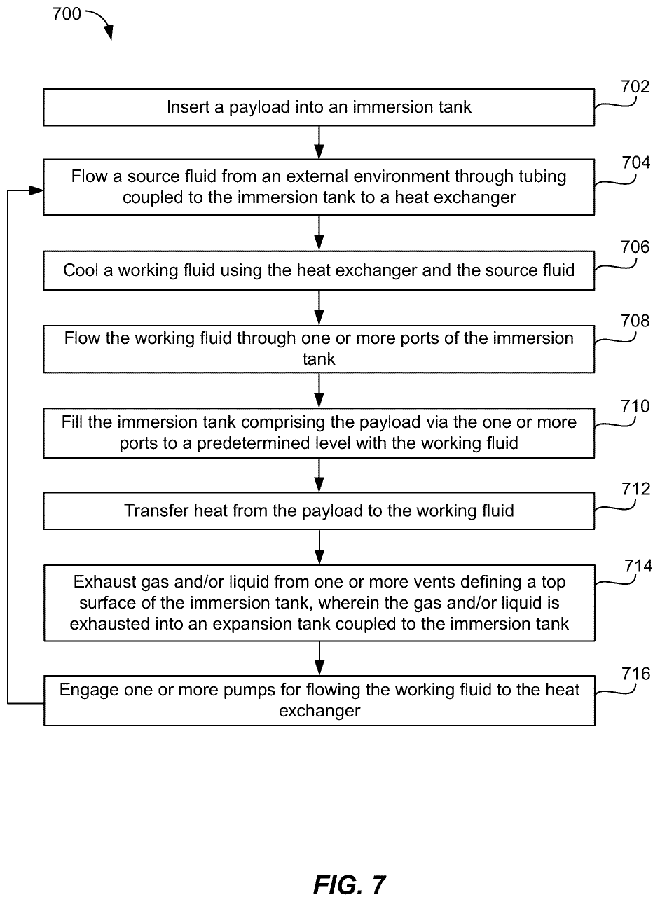

FIG. 7 is a flowchart of a method according to an embodiment of the present invention. In particular, FIG. 7 is a flowchart of a method for operating an immersion tank system. Method 700 includes inserting a payload into an immersion tank (702). The immersion tank may be similar to immersion tank 106 of system 100 and system 200 described with respect to FIGS. 1-6D. The method also includes flowing a source fluid from an external environment through tubing coupled to the immersion tank to a heat exchanger (704). Flowing the source fluid through the tubing to the heat exchanger may be used for cooling a working fluid using the heat exchanger and the source fluid (706).

The method further includes flowing the working fluid through one or more ports of the immersion tank (708). Various embodiments of the present disclosure may direct the fluid through alternative means and various surfaces of the immersion tank. For example, the working fluid may be flowed through one or more ports along a bottom surface, a top surface, one or more sidewalls, or any combinations thereof according to various embodiments. In one exemplary embodiment, the working fluid fills the immersion tank from the bottom up such that the working fluid pushes any excess air out of the immersion tank to fill the immersion tank with the working fluid and reduce splashing and air bubbles. For example, the method includes filling the immersion tank comprising the payload via the one or more ports to a predetermined level with the working fluid (710). The method further includes transferring heat from the payload to the working fluid (712). Payloads in the system generate heat during operation. Heat transfer between the payload and the working fluid may occur in a manner that would be understood by one having ordinary skill in the art.

In various embodiments, method 700 includes exhausting gas and/or liquid from one or more vents defining a top surface of the immersion tank (714). In some embodiments, the gas and/or liquid is exhausted into an expansion tank coupled to the immersion tank. For example, the expansion tank may be in fluid communication with the immersion tank for receiving any excess gas and/or liquid from the immersion tank. The method may include engaging one or more pumps for flowing the working fluid to the heat exchanger (716). The foregoing steps may be repeated until the payload is removed from the immersion tank. For example, to remove the payload from the immersion tank, a shock cage front access panel may be removed from a shock cage enclosing the immersion tank. A pump may be attached for draining the immersion tank through the one or more ports. The immersion tank may be slid out of the shock cage and an immersion tank cover may be removed for removing the payload from the immersion tank system. In some embodiments, the method includes draining the working fluid from the immersion tank via the one or more ports prior to removing the payload from the immersion tank.

Method 700 may further include monitoring various components of the immersion tank system. The method may include monitoring leaks using one or more control sensors in a shock cage enclosing the immersion tank. In various embodiments, one or more control sensors is a leak detection sensor that detects fluid in the shock cage of the immersion tank system. The method may further include monitoring a health metric of the working fluid using a fluid quality sensor. The method may further include monitoring a fluid level of the working fluid in the expansion tank using a fluid level sensor.

The technology described and claimed herein is not to be limited in scope by the specific preferred embodiments herein disclosed, since these embodiments are intended as illustrations, and not limitations, of several aspects of the technology. Any equivalent embodiments are intended to be within the scope of this technology. Indeed, various modifications of the technology in addition to those shown and described herein will become apparent to those skilled in the art from the foregoing description. Such modifications are also intended to fall within the scope of the appended claims.

1. An immersion tank system comprising:
an outer frame;
an immersion tank disposed within the outer frame, the immersion tank further comprising:
one or more ports;
one or more pumps;
a control system;
one or more sensors; and
a heat exchanger.

2. The immersion tank system of claim 1, wherein the one or more ports are configured to fill or drain the immersion tank.

3. The immersion tank system of claim 1, wherein the one or more ports are disposed on a surface of the immersion tank.

4. The immersion tank system of claim 3, wherein the surface is a bottom surface of the immersion tank.

5. The immersion tank system of claim 1, wherein the one or more pumps are variable speed pumps.

6. The immersion tank system of claim 1, further comprising sliding rails.

7. The immersion tank system of claim 1, further
comprising a shock cage disposed within the outer frame, the shock cage including a front access cover.

8. The immersion tank system of claim 7, wherein shock mounts coupled to the outer frame provide shock absorption for the immersion tank.

9. The immersion tank system of claim 7, wherein the immersion tank is configured to slide into and out of the shock cage on sliding rails.

10. The immersion tank system of claim 1, wherein the immersion tank further comprises a sealed access cover.

11.-16. (canceled)

17. A method for operating an immersion tank system adaptable for multiple environments, comprising:
a) inserting a payload into an immersion tank;
b) flowing a source fluid from an external environment through tubing coupled to the immersion tank to a heat exchanger;
c) cooling a working fluid using the heat exchanger and the source fluid;
d) flowing the working fluid through one or more ports of the immersion tank;
e) filling the immersion tank comprising the payload via the one or more ports to a predetermined level with the working fluid;
f) transferring heat from the payload to the working fluid;
g) exhausting gas and/or liquid from one or more vents defining a top surface of the immersion tank, wherein the gas and/or liquid is exhausted into an expansion tank coupled to the immersion tank; and
h) engaging one or more variable speed pumps for flowing the working fluid to the heat exchanger; and
repeating b) through h) until the payload is removed from the immersion tank.

18. The method of claim 17, further comprising monitoring leaks using one or more control sensors in a shock cage enclosing the immersion tank.

19. The method of claim 17, further comprising monitoring a health metric of the working fluid using a fluid quality sensor.

20. The method of claim 17, further comprising monitoring a fluid level of the working fluid in the expansion tank using a fluid level sensor.

21. The method of claim 17, further comprising draining the working fluid from the immersion tank via the one or more ports prior to removing the payload from the immersion tank.

22. A method for accessing an immersion tank system comprising:
providing an immersion tank comprising:
one or more ports;
one or more variable speed pumps;
a control system;
one or more control sensors;
one or more health sensors; and
a heat exchanger;
removing a shock cage front access panel from a shock cage enclosing the immersion tank;
attaching a pump and draining a working fluid from the immersion tank through the one or more ports;
sliding the immersion tank out of the shock cage;
removing an immersion tank cover from the immersion tank; and
removing a payload from the immersion tank system.

23. The method of claim 22, further comprising monitoring leaks using the one or more control sensors in the shock cage enclosing the immersion tank.

24. The method of claim 22, further comprising monitoring a health metric of the working fluid using a fluid quality sensor.

25. The method of claim 22, further comprising monitoring a fluid level of the working fluid in an expansion tank in fluid communication with the immersion tank using a fluid level sensor.

26. The method of claim 22, further comprising draining the working fluid from the immersion tank via the one or more ports prior to removing the payload from the immersion tank.
